(19) United States
(12) Patent Application Publication
(10) Pub. No.: US 2018/0328968 A1
(43) Pub. Date: Nov. 15, 2018

(54) EXCLUSIVE SMART ELECTRICITY METER

(71) Applicant: Marc Balich, Burlingame, CA (US)

(72) Inventor: Marc Balich, Burlingame, CA (US)

(21) Appl. No.: 15/592,625

(22) Filed: May 11, 2017

(51) Int. Cl. G01R 22/06; G01R 22/10

(52) U.S. Cl. CPC G01R 22/061; G01R 22/10

(57) ABSTRACT

A thin, “smart” electricity meter is provided that, in some embodiments, comprises a main housing having a relatively shallow depth and one or more “in” electricity-conducting prongs and one or more “out” electricity-conducting prongs. In some embodiments, the present invention may also provide for an LED display and a smart electrical meter processor and electricity-measuring elements located within the main housing.

### CROSS-REFERENCE TO RELATED APPLICATION

Not applicable.

### TECHNICAL FIELD

The present invention relates generally to the field of electricity meters and more specifically relates to a thin, “smart” electricity meter.

### BACKGROUND

Electricity is a standard part of many homes. And, generally speaking, that electricity is often generated elsewhere. Because there is a cost to this electricity generation, the cost is passed on to the end consumer. In a home, that cost is measured, generally speaking, in the amount of electricity used by the home. As such, electricity companies install electricity meters or require them to be installed.

Traditional electricity meters stick out from the wall or other surface a number of inches, and are themselves generally circular with an average diameter of eight to fourteen inches. Traditionally, electricity meters are mechanical instruments powered by the charge running through them. As such, their measurements are reliable, but not as precise as so-called “smart” electricity meters, which generally connotates a device that measures electricity usage via digital means.

Because electricity meters are generally located on or immediately adjacent to a home's electrical panel, electricians must either work with or work around electricity meters. This can create at least an inconvenience, and in other instances can even create a danger, to the electrician. And, although smart meters tend to be easier to read and use than traditional meters, many such smart meters are still large and cumbersome, thereby also creating the same size-related problems as traditional electricity meters. Therefore, a need exists for a thin, smart meter.

Various attempts to solve this problem have been made. One such attempt can be seen with respect to U.S. Pat. No. 6,262,672, incorporated by reference in its entirety herein, which generally discloses an electricity meter with some “smart” features. Although this disclosure does generally provide for a meter having an easy to read display and enhanced metering abilities, it fails to provide for a thin device having a robust portfolio of smart features.

Another attempt can be seen with respect to U.S. Patent Application Publication No. 2010/0253538 A1 incorporated by reference in its entirety herein, which generally discloses a smart meter-adaptation wherein an antenna element is either introduced or enhanced. While this disclosure is generally speaking an advancement in the smart meter art, it results in a smart meter that, in some embodiments, extends further from the wall that other smart meters.

Yet another attempt can be seen with respect to U.S. Patent Application Publication No. 2014/0019384 A1 incorporated by reference in its entirety herein, which generally discloses another smart meter, this one having advanced systems that can be remotely updated. While this disclosure does provide for enhanced smart meter functioning, it fails to disclose an advancement in the thinness of a smart meter.

Various attempts have been made to solve the problems which may be found in the related art but have thus far been unsuccessful. A need exists for a reliable thin, “smart” electricity meter to avoid the above-mentioned problems.

### SUMMARY OF THE INVENTION

It is to be understood that in the present disclosure, all embodiments are provided as illustrative and non-limiting representatives of many possible embodiments. In addition, the terms “is,” “can,” “will,” and the like are herein used as synonyms for and interchangeable with terms such as “may,” “may provide for,” and “it is contemplated that the present invention may” and so forth.

The present invention relates to a thin, “smart” electricity meter that overcomes the deficiencies of the prior art. It is contemplated that the present invention may provide a thin, “smart” electricity meter that is easier and safer to use or work around than other meters.

For purposes of summarizing, certain aspects, advantages, and novel features of the present invention are provided herein. It is to be understood that not all such aspects, advantages, or novel features may be provided in any one particular embodiment. Thus, the disclosed subject matter may be embodied or carried out in a manner that achieves or optimizes one aspect, advantage, or novel feature or group of features without achieving all aspects, advantages, or novel features as may be taught or suggested.

In view of the foregoing disadvantages inherent in the known art, the present invention provides a novel thin, “smart” electricity meter. The general purpose of the present invention, which will be described subsequently in greater detail, is to provide a thin, “smart” electricity meter that is easy to install, easy to read and use, as well as thin. The features of the invention which are believed to be novel are particularly pointed out and distinctly claimed in the concluding portion of the specification. These and other features, aspects, and advantages of the present invention will become better understood with reference to the following drawings and detailed description.

The unique features of the present invention may provide the following benefits for one or more consumers: it may be easy to use, easy to install, be easier to work around, and have an attractive, slim design.

In one embodiment, the present invention may comprise a thin smart meter having a front display, an information label, one or more function buttons, a LED display, an extruded back element, a main unit and/or main housing, one or more prongs, one or more 240-volt “in” prongs, one or more 240-volt “out” prongs, a base connection to the building, which in some embodiments may be a house, one or more silver metal rings, and one or more additional 240-volt prongs.

In some embodiments, the present invention's prongs may be configured to receive, conduct, or otherwise provide for voltages higher or lower than 240 volts. In some embodiments, the present invention may provide for the main unit/main housing element to be one or more inches “deep,” meaning the distance between its surface furthest from the building and its surface closest to the building may be one or more inches apart. In some embodiments, this distance may be less than one inch. In a preferred embodiment, this distance is one to two inches.

More specifically, in some embodiments, the present invention may comprise an electricity meter having a main housing, the main housing in turn having an internal portion, a front surface and a rear surface. In some embodiments, the internal portion may contain or provide for an electricity measuring element, which in some embodiments may contain one or more electricity measuring elements, one or more processors, and any element common to smart meters as that term is presently known in the art. The present invention may also provide for a display mounted within the front surface and at least one extruded back element and at least one building connection element, wherein the at least one extruded back elements is fixedly attached to the one or more building connection element.

Furthermore, the present invention may provide for at least one “in” prong, wherein the “in” prong is fixedly connected to the rear surface and passes through the rear surface into the internal portion, and wherein the “in” prong is in electrical communication with the electricity measuring element, the processor, or any other equivalent element normally associated with or found in a smart electricity meter, as that term is currently known in the art.

Additionally, the present invention may provide for at least one “out” prong, wherein the “out” prong is fixedly connected to the rear surface and passes through the rear surface into the internal portion, and wherein the “in” prong is in electrical communication with the electricity measuring element, the processor, or any other equivalent element normally associated with or found in a smart electricity meter, as that term is currently known in the art.

The present invention may also provide for at least one silver metal ring that may be removably located approximately at the juncture between the extruded back element and the base connection to the building, wherein the silver metal ring may removably provide a point of connection between the extruded back element and the base connection to building element.

In some embodiments the “in” prong may be a 240-volt “in” prong. In some embodiments, the “out” prong may be a 240-volt “out” prong. In some embodiments, the display may be an LED display. In some embodiments, the present invention may provide for one or more function buttons transverse the upper surface and are communicatively coupled to the at least one electricity measuring element, the processor, or any other element commonly associated with or found in a smart electricity meter, as that term is currently known in the art.

### BRIEF DESCRIPTION OF THE DRAWINGS

These and other features, aspects and advantages of the present invention will become better understood with regard to the following description, appended claims, and accompanying figures where:

FIG. 1 shows a perspective view of a thin, “smart” electricity meter in accordance with one embodiment of the invention.

FIG. 2 shows a planar view of a thin, “smart” electricity meter in accordance with one embodiment of the invention.

FIG. 3 shows an elevational view of a thin, “smart” electricity meter in accordance with one embodiment of the invention.

FIG. 4 shows a perspective view of a thin, “smart” electricity meter in accordance with one embodiment of the invention.

FIG. 5 shows an exploded perspective view of a thin, “smart” electricity meter in accordance with one embodiment of the invention.

FIG. 6 shows an alternate exploded perspective view of a thin, “smart” electricity meter in accordance with one embodiment of the invention.

### DETAILED DESCRIPTION

The present invention overcomes the limitations of the prior art by providing a new and more effective thin, “smart” electricity meter.

All dimensions specified in this disclosure are by way of example only and are not intended to be limiting. Further, the proportions shown in these Figures are not necessarily to scale. As will be understood by those with skill in the art with reference to this disclosure, the actual dimensions and proportions of any embodiment or element of an embodiment disclosed in this disclosure will be determined by its intended use.

It is to be understood that the drawings and the associated descriptions are provided to illustrate potential embodiments of the invention and not to limit the scope of the invention. Reference in the specification to “one embodiment” or “an embodiment” is intended to indicate that a particular feature, structure, or characteristic described in connection with the embodiment is included in at least an embodiment of the invention. The appearances of the phrase “in one embodiment” or “an embodiment” in various places in the specification are not necessarily all referring to the same embodiment.

Throughout the drawings, reference numbers are re-used to indicate correspondence between referenced elements. In addition, the first digit of each reference number indicates the figure where the element first appears.

As used in this disclosure, except where the context requires otherwise, the term “comprise” and variations of the term, such as “comprising,” “comprises” and “comprised” are not intended to exclude other additives, components, integers or steps.

In the following description, specific details are given to provide a thorough understanding of the embodiments. However, it will be understood by one of ordinary skill in the art that the embodiments may be practiced without these specific detail. Well known features, elements or techniques may not be shown in detail in order not to obscure the embodiments.

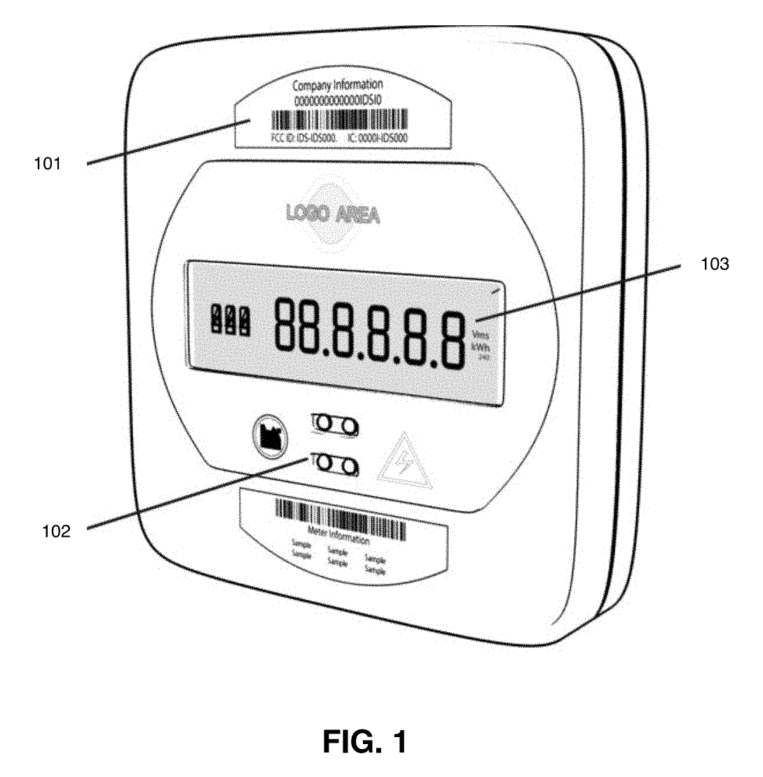

Turning attention to FIG. 1, a perspective view of a thin, “smart” electricity meter in accordance with one embodiment of the invention may be seen. In the embodiment depicted, a viewer may perceive information label 101, function buttons 102, and LED display 103.

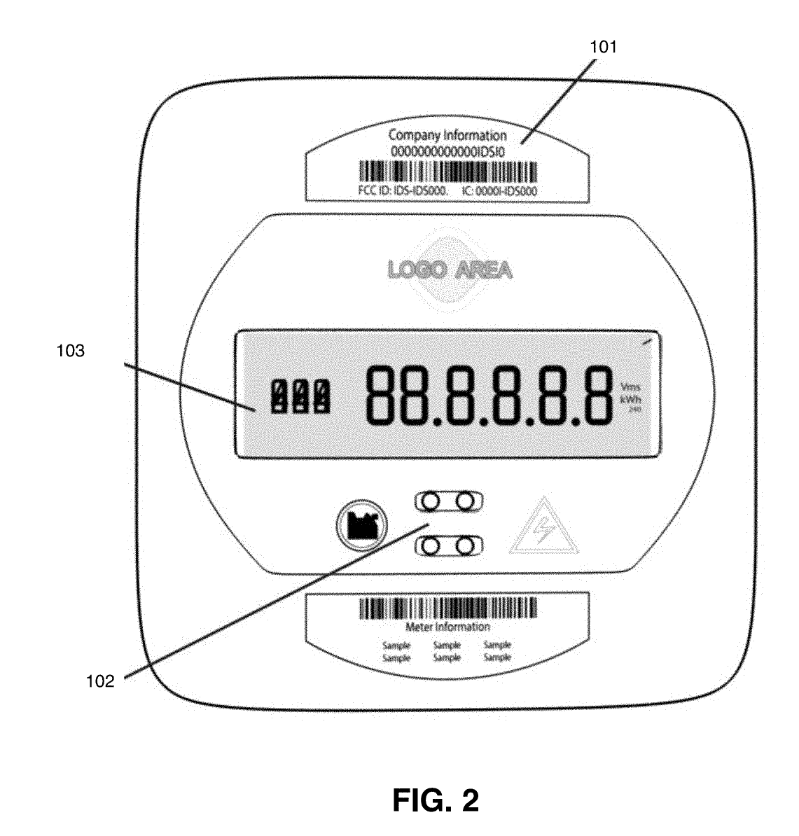

Turning attention to FIG. 2, a planar view of a thin, “smart” electricity meter in accordance with one embodiment of the invention may be seen. In the embodiment depicted, a viewer may perceive information label 101, function buttons 102, and LED display 103.

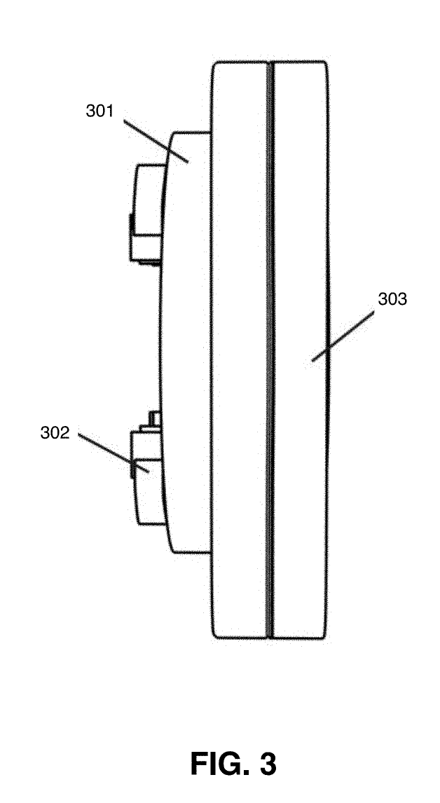

Turning attention to FIG. 3, an elevational view of a thin, “smart” electricity meter in accordance with one embodiment of the invention may be seen. In the embodiment depicted, a viewer may perceive extruded back 301, prongs 302, and main unit 303.

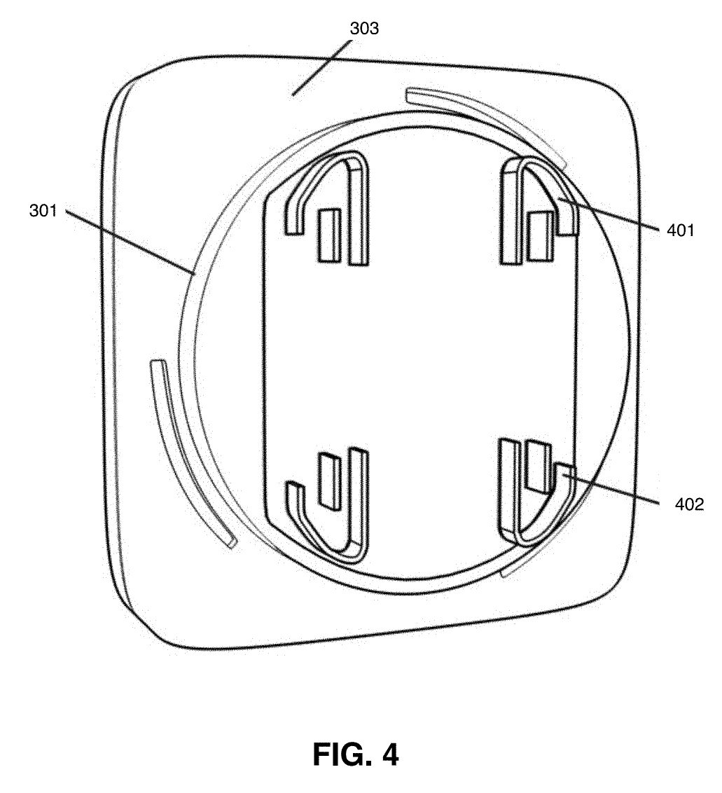

Turning attention to FIG. 4, a perspective view of a thin, “smart” electricity meter in accordance with one embodiment of the invention may be seen. In the embodiment depicted, a viewer may perceive extruded back 301 and main unit 303, as well as 240-volt “in” prongs 401 and 240-volt “out” prongs 402.

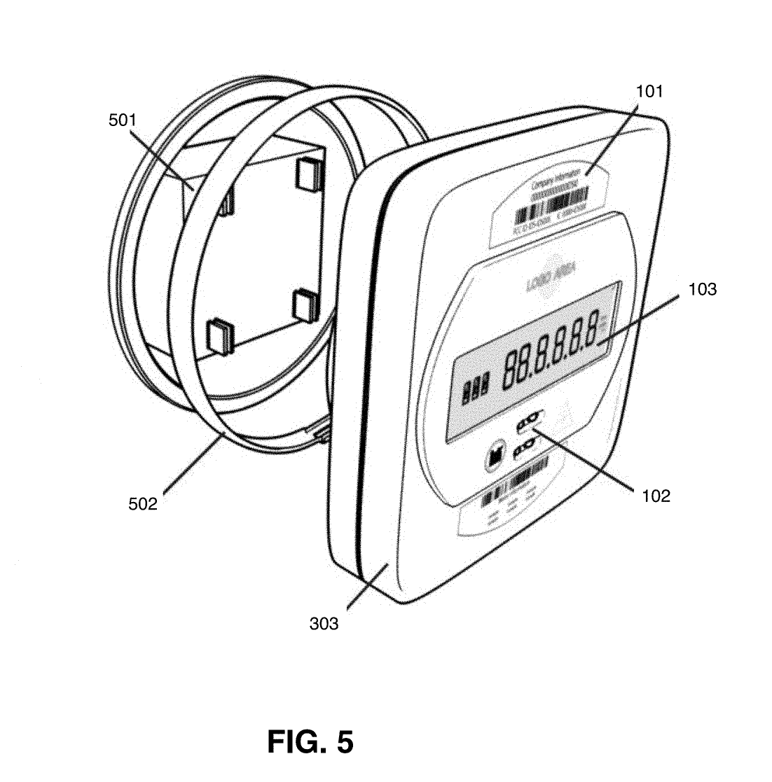

Turning attention to FIG. 5, an exploded perspective view of a thin, “smart” electricity meter in accordance with one embodiment of the invention may be seen. In the embodiment depicted, a viewer may perceive information label 101, function buttons 102, and LED display 103, along with main unit 303, base connection on building 501 and silver metal ring 502.

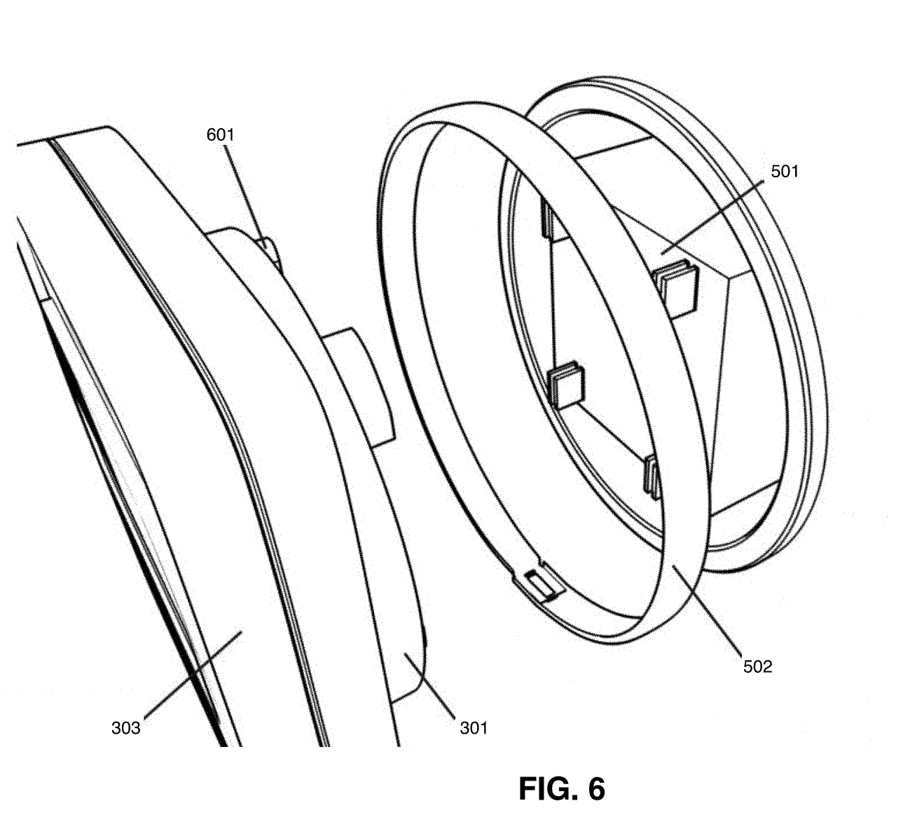

Turning attention to FIG. 6 shows an alternate exploded perspective view of a thin, “smart” electricity meter in accordance with one embodiment of the invention may be seen. In the embodiment depicted, a viewer may perceive 240-volt prongs 601, as well as base connection on building 501, silver metal ring 502, extruded back 301 and main unit 303.

### CONCLUSIONS, RAMIFICATIONS, AND SCOPE

Although the present invention has been described with a degree of particularity, it is understood that the present disclosure has been made by way of example and that other versions are possible. As various changes could be made in the above description without departing from the scope of the invention, it is intended that all matter contained in the above description or shown in the accompanying drawings shall be illustrative and not used in a limiting sense. The spirit and scope of the appended claims should not be limited to the description of the preferred versions contained in this disclosure.

All features disclosed in the specification, including the claims, abstracts, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent or similar purpose, unless expressly stated otherwise. Thus, unless expressly stated otherwise, each feature disclosed is one example only of a generic series of equivalent or similar features.

Any element in a claim that does not explicitly state “means” for performing a specified function or “step” for performing a specified function should not be interpreted as a “means” or “step” clause as specified in 35 U.S.C. § 112.

While the thin, “smart” electricity meter generally described herein has been disclosed in connection with a number of embodiments shown and described in detail, various modifications should be readily apparent to those of skill in the art.

What is claimed is:

1. An electricity meter, comprising:
a main housing having an internal portion, a front surface and a rear surface, the internal portion containing an electricity measuring element;
a display mounted within the front surface
at least one extruded back element and at least one building connection element, wherein the at least one extruded back elements is fixedly attached to the one or more building connection element;
at least one “in” prong, wherein the “in” prong is fixedly connected to the rear surface and passes through the rear surface into the internal portion, and wherein the “in” prong is in electrical communication with the electricity measuring element; and
at least one “out” prong, wherein the “out” prong is fixedly connected to the rear surface and passes through the rear surface into the internal portion, and wherein the “in” prong is in electrical communication with the electricity measuring element.

2. The electricity meter of claim 1, wherein at least one silver metal ring removably provides a point of connection between the extruded back element and the base connection to building element.

3. The electricity meter of claim 1, wherein the “in” prong is a 240-volt “in” prong.

4. The electricity meter of claim 1, wherein the “out” prong is a 240-volt “out” prong.

5. The electricity meter of claim 1, wherein the display is an LED display.

6. The electricity meter of claim 1, wherein the electricity measuring element is a smart electricity meter having at least one processor and at least one electricity measuring element;

7. The electricity meter of claim 1, wherein one or more function buttons transverse the upper surface and are communicatively coupled to the at least one electricity measuring element.

8. The electricity meter of claim 1, wherein one or more function buttons transverse the upper surface and are communicatively coupled to the at least one processor.
